(19) United States
(12) Patent Application Publication
(10) Pub. No.: US 2009/0001573 A1
(43) Pub. Date: Jan. 1, 2009

(54) Structure and method for wire bond integrity check on BGA substrates using indirect electrical interconnectivity pathway between wire bonds and ground

(76) Inventors: Phontara Jirawongsapiwat, Bangkok (TH); Preeyaporn Phakdee, Khlongluang (TH)

Correspondence Address: DEBORAH W. WENOCUR, 4057 AMARANTA AVE., PALO ALTO, CA, 94306, US

(21) Appl. No.: 11/650,907

(22) Filed: Jan. 8, 2007

(51) Int. Cl. H01L 23/52; B23K 37/00

(52) U.S. Cl. 257/738; 228/103; 228/104; 228/102; 257/E23.141

(57) ABSTRACT

An invention providing improvement in integrity testing of wire bonds between an IC die and a BGA substrate.

The invention includes a BGA integrated circuit package comprising:
1) a BGA substrate having conducting bond fingers and a grounded feature on a first side thereof; 2) an IC die electrically connected to the conducting bond fingers with wire bonds; the BGA substrate configured to be formed into a singulated unit with the IC die; wherein the BGA substrate does not have direct electrical connection on the first side thereof between the bond fingers and the grounded feature; 4) the BGA substrate including an indirect electrical connection pathway from each wire bond to the grounded feature that enables electrical integrity testing for the wire bonds; the indirect electrical connection pathway configured so that at least a portion of each indirect electrical connection pathway is not present on the singulated unit.
The invention further includes a method for bonding an integrated circuit (IC) die to a BGA substrate, said BGA substrate configured to be formed into a singulated unit with said IC die, said method including testing electrical integrity of a wire bond between a) a bond finger on a first side of said BGA substrate and b) a bonding pad on said IC die, wherein said substrate does not have direct electrical connections on said first side between said bond fingers and a grounded feature on said first side; the method comprising the steps of:
applying a voltage through said wire bond on said BGA substrate to said grounded feature, through an indirect electrical connection pathway at least a portion of which is not present on said singulated unit; and
measuring if there is current flow through said pathway.
The invention further includes an integrated circuit (IC) die mounted on and packaged with the BGA substrate, formed by a method comprising the steps of:
   making electrical connections between the IC die and the substrate, including forming bond finger wire bonds;
   testing the electrical integrity of each bond finger wire bond according to the method of this invention;
   forming a package mold on the substrate;
   attaching solder balls to the bottom side of the substrate; and
   singulating the substrate.

### FIELD OF THE INVENTION

This invention is in the field of integrated circuit packaging, and more particularly to design of high-density substrate designs for OSP surface finishes on BGA IC packages.

### BACKGROUND OF THE INVENTION

As in every aspect of integrated circuit processing, packaging methods have of necessity been greatly affected as critical dimensions decrease and circuit speed and complexity increases. Packaging methods which are compatible with high density IC's include the use of the Ball-Grid Array (BGA) substrate. The basic process flow of the packaging is illustrated in FIG. 1. In step 100, patterned substrate strips are obtained from the vendor. The substrates are generally comprised of an insulating BT resin core with layers of Cu cladding above and below. The copper cladding is etched away except in the specific areas used to connect features, leaving conducting “traces” atop insulator. An insulating solder resist coating is formed after the traces are patterned and etched. In certain regions, Solder Resist Openings (SRO's) are formed to expose the copper. As will be described hereinafter, substrates obtained from the vendor have a metallic plating, generally Ni—Au, on the Cu regions which are exposed. These regions include bond fingers, solder ball pads, fiducials, and mold gates. In step 105, the substrate strips pass through incoming quality control. In step 110, the IC dice are attached to the substrates. In step 115, the wires which provide contacts to the IC are bonded from the bond fingers on the substrate to the bonding pads on the IC. In step 120, the package mold is formed, with mold material admitted via openings known as mold gates. In general, electrical connection is made between the mold gates, the bond fingers, and across the edges of the substrates via tie bars on the top copper layer of the substrate. Tie bars on the bottom copper layer of the substrate are connected to fiducials. Copper-plated Vias or “through holes” provided by the substrate vendor make a connection between the top and bottom copper of the substrate. These vias are generally created either by mechanical drill bits or by lasers. In step 125, the solder balls are attached to the back side of the substrate for future connection to the Printed Circuit Board (PCB). In step 130, the substrates are singulated, i.e., separated from the substrate strips, to create the final packaging unit for mounting on the PCB. At this point, the singulated substrates are also separated from the tie bars.

Contacts to certain features of the copper layers of the substrate, such as the bond fingers and the solder ball pads, are facilitated by plating or deposition of a conducting layer thereon. Ni—Au plating has traditionally been utilized. However, improved reliability and crack and drop resistance of the solder balls are achieved by using Organic Solderability Preservative (OSP) coating between the substrate and solder balls, known as “ball pad OSP”, on the substrate backside. OSP as used in BGA packages is described in “The study of OSP as reliable surface finish of BGA substrate”, Chang, D. Bai, F. Wang, Y. P. Hsiao, C. S., Siliconware Precision Ind. Co. Ltd., Taichung, Taiwan; Electronics Packaging Technology Conference, 2004. EPTC 2004.

The combination of Ni/Au plating on the front side and the OSP coating necessitates modifications to the substrate connection layout, i.e., to the connectivity between the tie bars and a grounded feature, which is generally the mold gates.

An important aspect of the wire bonding process of FIG. 1, step 115, is an electrical integrity check which verifies that the wire is completely bonded onto the bond fingers. If an incomplete wire bond (resulting in an open circuit and/or incomplete grounding) occurs, the wire bonding machine stops, and operator assistance is requested. This functional test is necessary to confirm that no package unit containing an incomplete wire bond is sent on to the next process or to the customer.

A problem exists for the high density line/space PCB/substrate designs with ball pad OSP, which do not have a direct circuit connection on the top copper layer from the bond fingers to the tie bar and therefore to the grounded mold gate, whereas the layout of the bottom copper layer connects the ball pads to the bottom side tie bar. This substrate design allows for verification of via quality by inducing electrolytic Ni/Au plating current from the bottom, which will induce plating on the top side only when the copper plating on the electrically connected via to the Ni—Au plating region in question is of good quality. (Verification of via quality has become necessary, since historically, use of poor drill bits for creating the via holes could cause uneven breaking of the resin, which could in turn result in incomplete copper plating and poor electrical connectivity. As a result, the bond finger connected to that via hole would be improperly Ni—Au plated.) However, not having the bond fingers connected to the top side tie bar prevents a closed circuit which would allow for the automatic wire bonding circuit integrity check. Currently, either the sensitivity of the bond integrity check is reduced, or the function turned off entirely. Therefore, it is possible that broken wires or incomplete bonds will not be located, and go on to subsequent processes. To avoid this problem, either visual inspection or testing of 100% of the circuits is required.

A method for providing an indirect electrical connectivity pathway between the grounded feature, generally the mold gate, and the bond fingers for ball pad OSP surface finish designs, which would simultaneously enable wire bonding circuit integrity check, and also enable verification of via quality by inducing electroplating current from the substrate backside only, would be an important improvement in high density BGA IC packaging.

### SUMMARY OF THE INVENTION

The present invention provides: A BGA integrated circuit package comprising:

1) a BGA substrate having conducting bond fingers and a grounded feature on a first side thereof; 2) an IC die electrically connected to the conducting bond fingers with wire bonds; the BGA substrate configured to be formed into a singulated unit with the IC die; wherein the BGA substrate does not have direct electrical connection on the first side thereof between the bond fingers and the grounded feature; 4) the BGA substrate including an indirect electrical connection pathway from each wire bond to the grounded feature that enables electrical integrity testing for the wire bonds; the indirect electrical connection pathway configured so that at least a portion of each indirect electrical connection pathway is not present on the singulated unit.

The invention further includes a method for bonding an integrated circuit (IC) die to a BGA substrate, said BGA substrate configured to be formed into a singulated unit with said IC die, said method including testing electrical integrity of a wire bond between a) a bond finger on a first side of said BGA substrate and b) a bonding pad on said IC die, wherein said substrate does not have direct electrical connections on said first side between said bond fingers and a grounded feature on said first side; the method comprising the steps of:

applying a voltage through said wire bond on said BGA substrate to said grounded feature, through an indirect electrical connection pathway at least a portion of which is not present on said singulated unit; and

measuring if there is current flow through said pathway.

The invention further includes an integrated circuit (IC) die mounted on and packaged with the BGA substrate, formed by a method comprising the steps of:
making electrical connections between the IC die and the substrate, including forming bond finger wire bonds;
testing the electrical integrity of each bond finger wire bond according to the method of this invenetion;
forming a package mold on the substrate;
attaching solder balls to the bottom side of the substrate; and
singulating the substrate.

### BRIEF DESCRIPTION OF THE FIGURES

FIG. 1 illustrates the basic process flow of high density BGA IC packaging.

FIG. 2a shows a portion of a PCB/BGA substrate strip layout, top view.

FIG. 2b shows a detailed portion of FIG. 2a.

FIG. 2c shows a portion of a PCB/BGA substrate strip layout, bottom view.

FIG. 2d shows a detailed portion of FIG. 2c.

FIG. 3 shows a closeup view of a portion of a PCB/BGA substrate strip with silicon die attached and wire bonds shown, top view.

FIG. 4a shows a portion of a high density (Line and Space) and Ball Pad OSP surface finish PCB/substrate strip layout, from the top view.

FIG. 4b shows a detailed region of FIG. 4a, showing a single portion 400 of a single BGA IC package body from the top view.

FIG. 4c shows the same portion of a high density (Line and Space) and Ball Pad OSP surface finish PCB/substrate strip layout, from the bottom view.

FIG. 4d shows a detailed region of FIG. 4c, showing a single portion 445 of a single BGA IC package body.

FIG. 5a illustrates the lack of circuit connectivity through the wire bonds if there is no bypass connection.

FIG. 5b illustrates our inventive solution to the lack of circuit connectivity shown in FIG. 5a, as seen from the top side.

FIG. 6 outlines the method of wire bond integrity testing using the inventive bypass via holes.

### DETAILED DESCRIPTION OF THE INVENTION

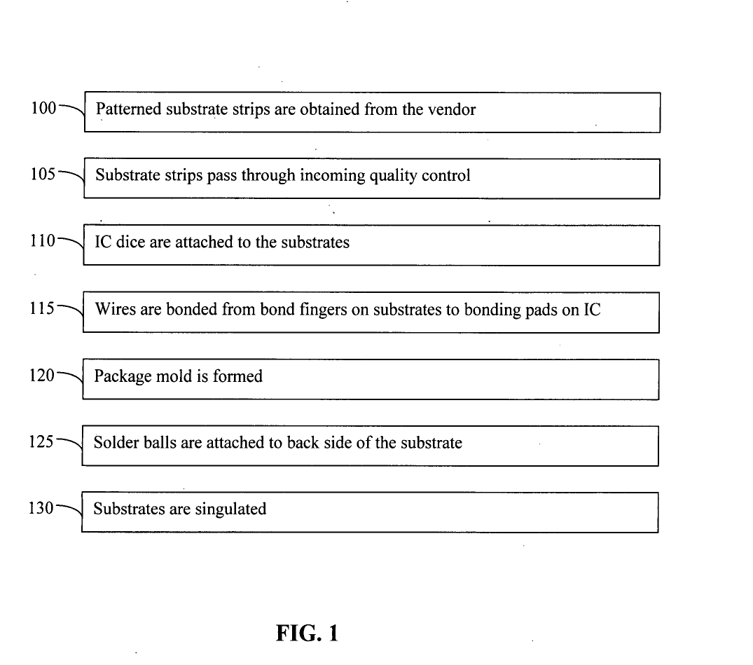

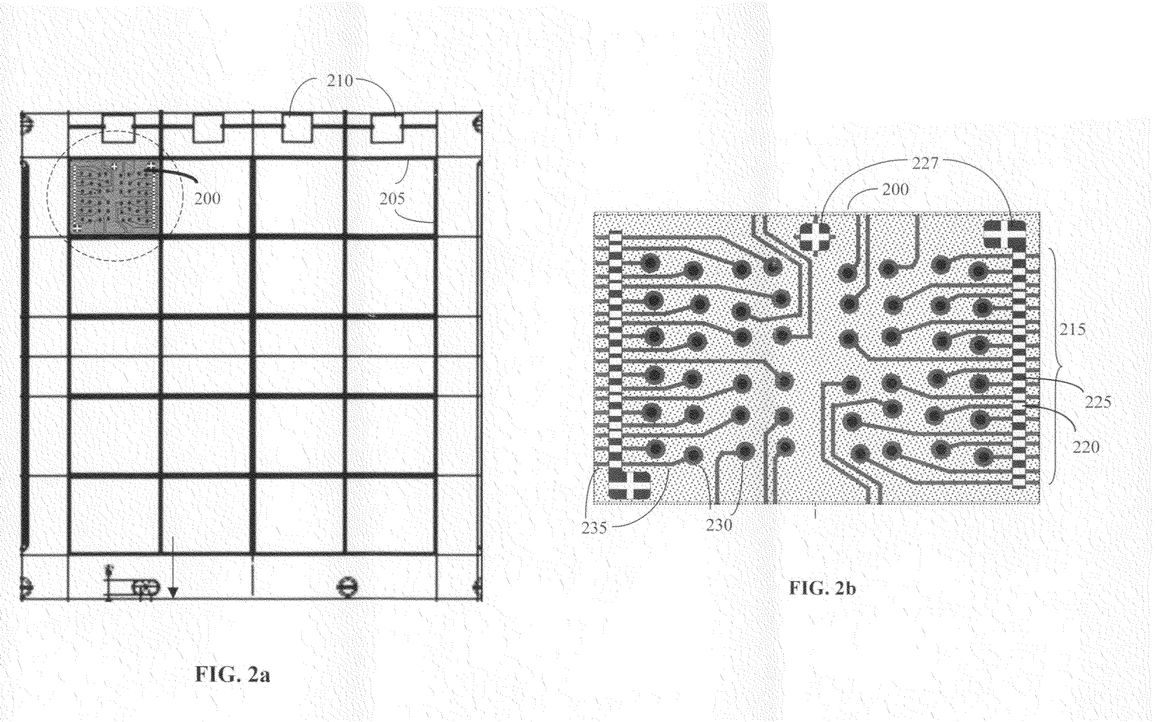

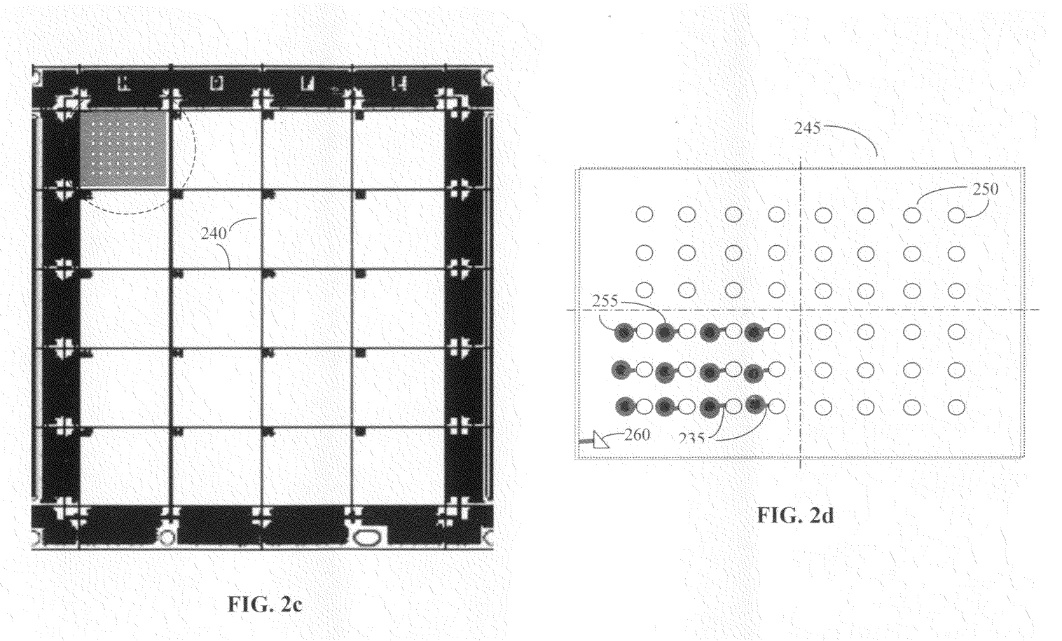

FIG. 2a shows a portion of a traditional PCB/substrate strip layout, from the top view. Regions 200 each comprise the substrate portion of a single BGA IC package body. Regions 200 are bordered by conducting Top Tie Bars 205. Mold gates 210 are connected to top tie bars 205, and are in a region outside BGA package body 200. When the packages are separated, also known as singulated, tie bars 205 are separated from substrate regions 200. As described in FIG. 1, the singulation occurs after the IC die is mounted on the substrate, wire bonds are made, the package is molded, and solder balls are attached. The singulated, molded package with IC mounted and bonded and solder balls attached is known as a “singulated unit”.

FIG. 2b shows a detailed region of FIG. 2a, showing a single portion 200 of a single BGA IC package body. Bond finger solder resist openings 215 expose conducting bond fingers 220, to which wire bonds to the IC are attached, and insulating regions 225. Fiducials 227 aid in alignment. Copper-plated in-package via holes 230 extend from the top to the bottom surface of the substrate. The via holes 230 provide electrical connectivity between the top and bottom substrate surface. Cu traces 235 make electrical connections, e.g., between via holes 230 and bond fingers 220, and between bond fingers 220 and tie bars 205. FIG. 2c shows the same portion of a traditional PCB/substrate strip layout, from the bottom view, including bottom side tie bars 240, and FIG. 2d shows a detailed region of FIG. 2c, showing a single portion 245 of a single BGA IC package body. The IC package body is the portion of the substrate which will eventually become a singulated unit. Ball pads 250 are placed in an array and are connected to via holes 255 (only some of which are shown) by traces 235 (also only some of which are shown), but no copper traces 235 connect the balls to the bottom side tie bars. The bottom side tie bars are utilized, first of all, as a visual reference for saw singulation, and may also be connected to Pin One Identifier 260 (which is Ni—Au plated and serves to properly identify the orientation of the ball matrix with respect to the PCB. This traditional configuration of substrate layout is generally utilized when Ni/Au plating is used on both the front side and back side of the substrate, for both the bond fingers, fiducials, and mold gate on the frontside, and for the, solder ball pads, and fiducials on the backside —The electric current for the electrolytic Ni/Au plating is applied from the frontside by way of the tie bars which connect through the via holes to the backside. Plating occurs nearly simultaneously on the front side and back side when the substrate is immersed in the electrolytic plating solution, if the vias are good and electrically conducting.

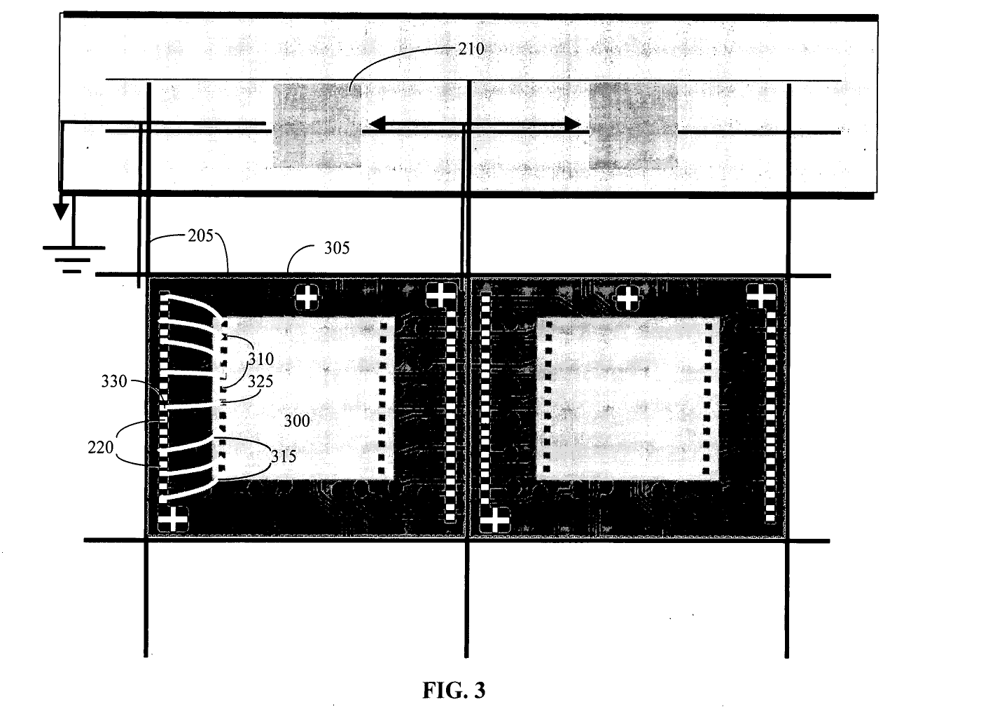

FIG. 3 shows a portion of a PCB substrate strip with silicon die 300 mounted atop substrate portion 305. Bonding pads 310 on die 300 are placed for making contact to off-die. In this case, bond wires 315 connect bond fingers 220 and bonding pads 310. In the wire bonding process, generally the mold gates 210 connected to top layer tie bars 205 (which are connected to the bond fingers) are grounded and used for an electrical integrity check to be sure that the wires are completely bonded on the bond fingers. The bonding machine first attaches a wire to a bonding pad 310 on the IC using a ball bond 325. It then attaches the other end of the same wire to a bond finger on the substrate using a wedge bond 330. If the ball bond is not secure, the wire tension will be insufficient to do the wedge bond, and the bonding machine will stop due to physical, not electrical, characteristics. After the wedge bond is done on bond finger, the wire is cut, and so a bad wedge bond could result without detection. To avoid this, the wire bond machine applies an electrical pulse through the wire before cutting wire to determine electrical connectivity, i.e., to be sure that the wire is securely and electrically connected to the bond finger. If the wire bond is defective or incomplete, an open circuit and incomplete grounding results, therefore no signal is sent. In this case, the wire bonding machine stops and operator assistance is requested. This functional test of the wire bond integrity is necessary to assure that no incomplete or defective wire bonds are passed on to the next process or to the customer.

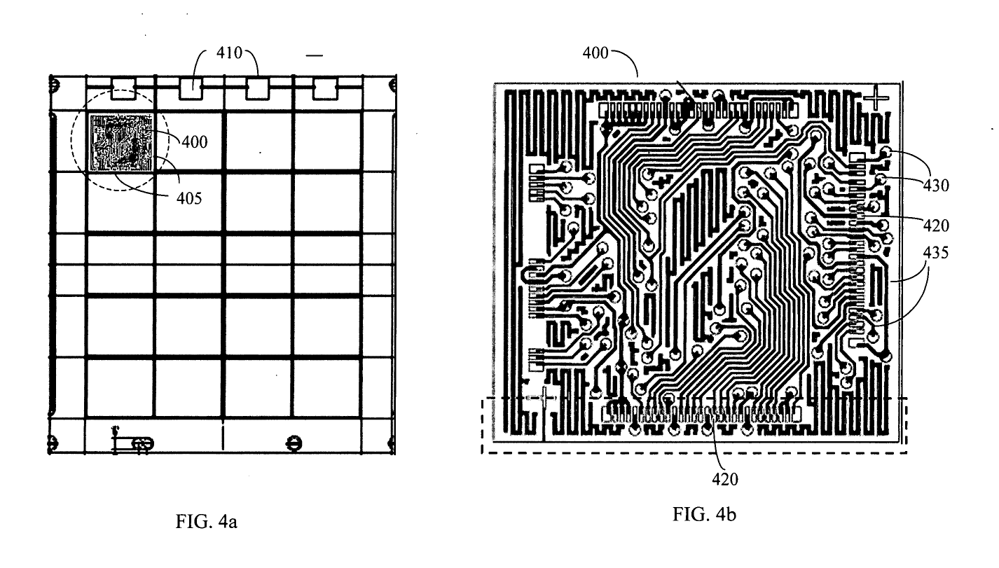

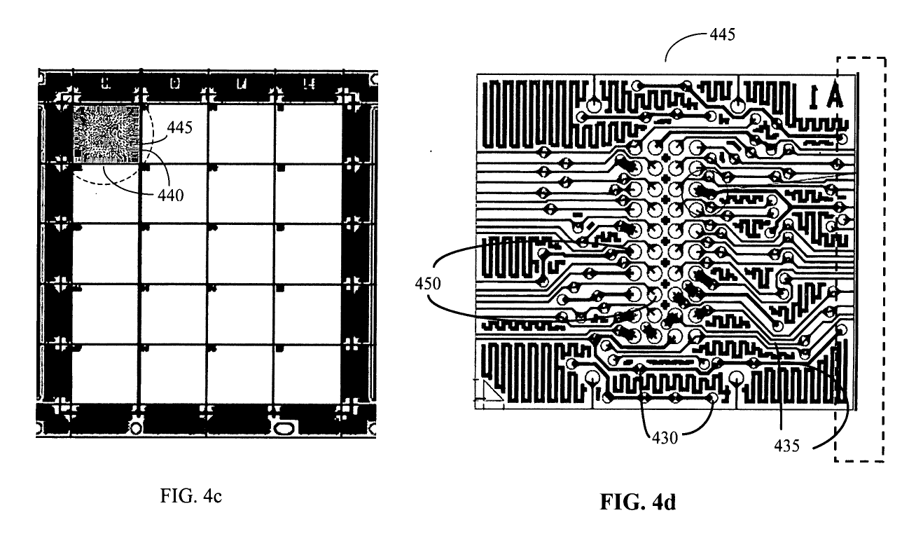

FIG. 4a shows a portion of a high density (Line and Space) and Ball Pad OSP surface finish PCB/substrate strip layout, from the top view. Regions 400 each comprise the substrate portion of a single BGA IC package body. Regions 400 are bordered by conducting Top Tie Bars 405. Mold gates 410 are connected to top tie bars 405, and are in a region outside BGA package body 400.

FIG. 4b shows a detailed region of FIG. 4a, showing a single portion 400 of a single BGA IC package body from the top view. Conducting bond fingers 420 are attached to wire bonds to the IC. Copper-plated via holes 430 extend from the top to the bottom surface of the substrate. The via holes provide electrical connectivity between the top and bottom substrate surface. Cu traces 435 make electrical connections, e.g., between via holes 430 and bond fingers 420. Note, however, that there are no traces connecting bond fingers 420 and tie bars 405 on the top side. The purpose for this design feature for the OSP surface finish substrate designs is to facilitate the testing of vias during the Ni—Au plating process, as described below. The OSP process includes use of a lamination sheet on the back side to protect of the solder ball pads during the Ni—Au plating of the front side, then the subsequent removal of the lamination sheet and deposition of the OSP coating on the solder ball pads.

During the Ni—Au plating of the frontside, while the solder ball pads are protected, it is preferred to send the electroplating current from the back side. Assuming the vias are complete and well plated, the current will pass through to the front side and the Ni—Au plating will proceed accordingly. If there are incomplete or poorly copper-plated vias, the electroplating current will be interrupted and Ni—Au plating will not occur properly on regions connected to the poor via. Sending the plating current from the back only, therefore, proves a test of via quality. For this reason, there are no traces electrically connecting the frontside tie bar with the vias. During Ni—Au plating, the package is held by a clamp through which the electroplating current is passed. This clamp contacts both the top and the bottom tie bars. Therefore, if the top tie bars were electrically connected to the bond fingers, electroplating current would pass current directly from the frontside and plate whether or not the vias were good. Thus, there would be no indication of via quality. In contrast, in the traditional case where Ni—Au is plated on both the front side and the back side, the symmetry of the arrangement allows for via quality testing if either the top or the bottom tie bar, but not both, are connected to the vias. Since wire bond integrity testing is straightforward if the Ni—Au electroplating current was passed to the vias from the front side, this method was traditionally used. The necessity of inducing the electroplating from the back side for the OSP design causes the complication in wire bond integrity testing which is addressed by the present invention.

FIG. 4c shows the same portion of a high density (Line and Space) and Ball Pad OSP surface finish PCB/substrate strip layout, from the bottom view, including bottom side tie bars 440, and FIG. 4d shows a detailed region of FIG. 4c, showing a single portion 445 of a single BGA IC package body. Ball pads 450 are placed in an array, and copper traces 435 connect the balls to the bottom side tie bars.

The design difference for the high density (Line and Space) and Ball Pad OSP surface finish PCB/substrate strip layout as described above, wherein there is no connection between the top side tie bars (which are connected to the mold gates) and the bond fingers, prevents the wire bond integrity check from being performed. We have developed a method to overcome this problem so as to enable the wire integrity check for the high density (Line and Space) and Ball Pad OSP surface finish PCB/substrate strip layout.

Our method provides a temporary indirect electrical connection pathway from a grounded feature, generally the mold gate, and top tie bar, to the bond fingers on the top side. This temporary connection will be severed when the packages are singulated, i.e., at least a portion of the indirect electrical connection pathway is not present on the singulated unit, so as to avoid grounding of the IC bonding pads. Therefore the connection is called a dummy connection. In order to insure that the temporary connection is severed when the packages are singulated, a portion of the connection is positioned outside the BGA IC body package. Since the temporary connection is no longer present for the final packaged IC product, the inventive product may be termed an intermediate product, which is found at an intermediate step in the processing.

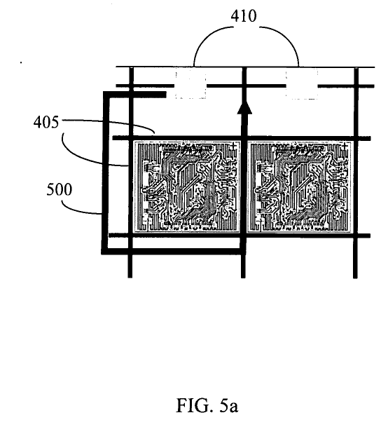

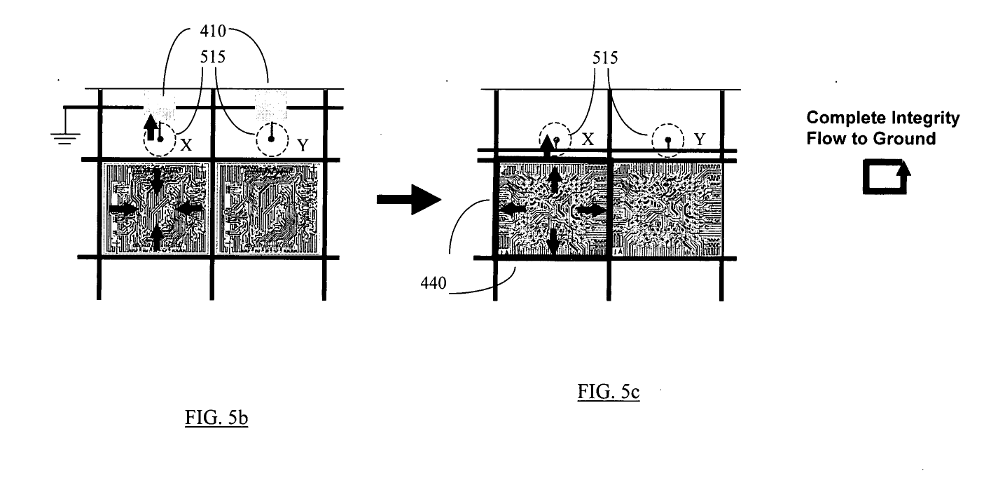

FIG. 5a, showing the top side as in FIG. 4b, illustrates the lack of circuit connectivity through the wire bonds if there is no bypass connection between the mold gates 410, top tie bars 405, and bond fingers 420. In this case, any voltage applied at the mold gate is restricted to causing current flow 500 around the top tie bars which are disconnected from the bond fingers and therefore the wire bonds.

FIG. 5b illustrates a preferred embodiment of our inventive solution to the lack of circuit connectivity shown in FIG. 5a, as seen from the top side. Dummy bypass via holes 515 are added, located outside the BGA IC package body, which are electrically connected to the mold gates 410 with copper traces. The dummy bypass via holes typically have diameter in the range between 0.1 mm-0.15 mm. They are created at the same time as the in-package vias, and are plated with copper at the same time as the vias. FIG. 5c shows the bottom side view including the bypass via holes. As shown by the arrows on FIGS. 5b and 5c, current flows from the bonding machine through the wire wedge bonds 330 to bond fingers 420 on the top side, through inner package via holes 430 to the back side, where the via holes are connected to ball pads 450 and to bottom side tie bar 440 with copper traces. The bottom side tie bar 440 is directly connected to bypass via holes 515, which are in turn, on the front side, directly connected to mold gates 500 which are grounded.

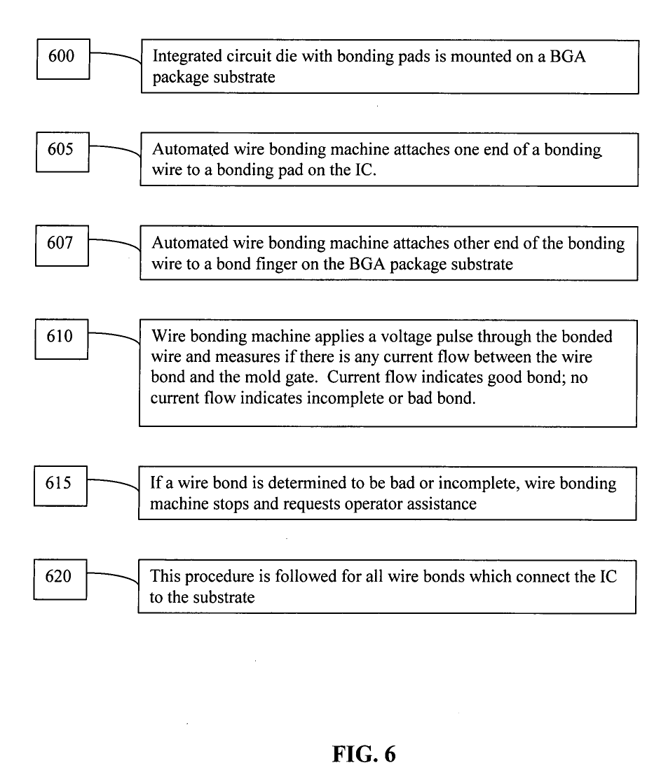

FIG. 6 outlines the method of wire bond integrity testing using the inventive bypass via holes.

In step 600, an integrated circuit die with bonding pads is mounted on a package substrate, which may be a BGA or FBGA substrate. The substrate is provided with conducting bond fingers on the top side, tie bars (also known as bus lines) on the top and bottom sides, solder ball pads on the back side, conducting via holes from the front side to the back side, conducting traces connecting the bond fingers with via holes and also connecting the via holes and solder ball pads with the bottom side tie bar. Also provided on the substrate are bypass via holes outside the BGA IC package body, according to the inventive method described herein.

In step 605, an automated wire bonding machine attaches one end of a bonding wire to a bonding pad, generally with a ball bond, on the integrated circuit.

In step 607, the automated wire bonding machine attaches the other end of the bonding wire to a bond finger, generally with a wedge bond, on the BGA package substrate. Note that it is possible to reverse steps 605 and 607, though that is not commonly done.

In step 610, the wire bonding machine applies a voltage pulse through the bonded wire and measures if there is any current flow between the wire bond and the grounded feature, generally the mold gate. If there is current flow, the wire bond being tested is determined to be good. If there is an incomplete wire bond, resulting in an open circuit, there is no current flow.

In step 615, if a wire bond is determined to be incomplete, the wire bonding machine stops and requests operator assistance.

In step 620, this procedure is followed for all wire bonds which connect the IC to the substrate.

The completion of the IC packaging includes:

1) forming a package mold on the substrate;

2) attaching solder balls to the bottom side of the substrate; and

3) singulating the substrate.

Upon singulation, the dummy bypass via and tie bars are severed from the IC package body, so that there is no remaining electrical connection from the IC bonding pads and bond fingers to ground, and therefore at least a portion of the indirect electrical connectivity pathway comprised in part by the dummy bypass via does not remain for the singulated unit.

Our inventive method enables electrical integrity testing of wire bonds for IC packaging substrates which do not have a direct top side connection between bond fingers and top side tie bars and/or mold gates. The exemplary substrate type described in the particular embodiments disclosed herein is high density (Line/Space) BGA substrate design with ball pad OSP finish. It should be apparent to those skilled in the art that modifications can be made to those specifics without departing from the inventive concept. By way of example, the method and structure can be applied to FBGA (Fine Pitch Ball Grid Array) packages as well as more standard BGA, Chip Scale Packaging (CSP), (package only 10-20% larger than die) and system scale PCB's. The technique is applicable to any BGA-type package which has solder balls on bottom and is over-molded on the top side with some resin, even if not entirely over-molded. The scope of the invention should be construed in view of the claims.

With this in mind, we claim:

1. A BGA integrated circuit package comprising:
a BGA substrate having conducting bond fingers and a grounded feature on a first side thereof;
an IC die, said IC die electrically connected to said conducting bond fingers with wire bonds;
said BGA substrate configured to be formed into a singulated unit with said IC die;
wherein said BGA substrate does not have direct electrical connection on said first side thereof between said bond fingers and said grounded feature;
said BGA substrate including an indirect electrical connection pathway from each said wire bond to said grounded feature that enables electrical integrity testing for said wire bonds;
said indirect electrical connection pathway configured so that at least a portion of each said indirect electrical connection pathway is not present on said singulated unit.

2. The integrated circuit package of claim 1, wherein
a) said BGA substrate includes a first BGA IC package body region, and a second region outside said BGA IC package body; and
b) said indirect electrical connection pathway from said wire bonds to said grounded feature includes an electrical connection between said grounded feature on said substrate first side and solder ball pads on a second side of substrate, said solder ball pads being electrically connected to said bond fingers by vias in said first BGA IC package body region;
c) said electrical connection being in said second region outside said BGA IC package body.

3. The integrated circuit package of claim 2, wherein
a) said electrical connection between said grounded feature on said substrate strip first side and said solder ball regions on said at least one substrate second side comprises a dummy bypass via between said substrate first side and said substrate second side;
b) said dummy bypass via being in said second region outside said BGA IC package body, said dummy bypass via being electrically connected to said solder ball pads regions on said substrate, and to said grounded feature on said substrate first side.

4. The integrated circuit package of claim 3, wherein said dummy bypass via is electrically connected to a second side tie bar which is electrically connected to said solder ball pad regions by Cu traces; and wherein said bypass via is electrically connected to said grounded feature by a Cu trace.

5. The integrated circuit package of claim 1, wherein said grounded feature is said mold gates.

6. The integrated circuit package of claim 1, wherein said BGA IC package body is selected from the group consisting of:
FBGA (Fine Pitch Ball Grid Array), high density (Line and Space) and Ball Pad OSP surface finish PCB/substrate, standard BGA, Chip Scale Packaging (CSP), and system scale PCB's.

7. A method for bonding an integrated circuit (IC) die to a BGA substrate, said BGA substrate configured to be formed into a singulated unit with said IC die, said method including testing electrical integrity of a wire bond between a) a bond finger on a first side of said BGA substrate and b) a bonding pad on said IC die, wherein said substrate does not have direct electrical connections on said first side between said bond fingers and a grounded feature on said first side; the method comprising the steps of:
applying a voltage through said wire bond on said BGA substrate to said grounded feature, through an indirect electrical connection pathway at least a portion of which is not present on said singulated unit; and
measuring if there is current flow through said pathway.

8. The method of claim 7, wherein said wire bond is performed by an automated wire bonding machine, and wherein;
if there is no said current flow through said pathway, said automated wire bonding machine is stopped and operator assistance is requested.

9. The method of claim 7, wherein;
said BGA substrate includes a first BGA IC package body region, and a second region outside said BGA IC package body; and
said indirect electrical connection pathway includes a dummy bypass via through said BGA substrate, in said second region outside said BGA IC package body.

10. The method of claim 9, wherein said indirect electrical connection pathway comprises:
a) said wire bond electrically connected to said bond finger;
b) said bond finger electrically connected to a conducting via through said substrate in said first region;
c) said conducting via electrically connected to a solder ball pad on a second side of said substrate;
d) said solder ball pad electrically connected to a second side tie bar on said second side of said substrate, through conducting traces;
e) said second side tie bar electrically connected to said conducting dummy bypass via;
f) said conducting dummy bypass via electrically connected to said grounded feature on said top side in said second region;
g) wherein said dummy bypass via is disconnected from said solder ball pad when said BGA substrate is formed into a singulated unit.

11. The method of claim 8, further including the steps of:
a) mounting said IC die on said BGA package substrate;
b) said automated wire bonding machine attaching a first end of a bonding wire to a bonding pad on said IC with a first wire bond;
c) before or after step b), said automated wire bonding machine attaching a second end of said bonding wire to a bond finger on said BGA package substrate with a second wire bond, prior to said step of applying a voltage through said second wire bond on said substrate to said grounded feature through an indirect electrical connection pathway at least a portion of which is not present on said singulated unit; and
d) if the electrical integrity of second wire bond is determined to be good, said automated wire bonding machine cutting the unbonded portion of said bonding wire.

12. The method of claim 11, wherein steps b)-d) are repeated for each said bonding wire attaching said IC to said substrate.

13. The method of claim 10, wherein said grounded feature is a mold gate.

14. The method of claim 11, wherein said first wire bond is a ball bond and said second wire bond is a wedge bond.

15. The method of claim 7, wherein said BGA substrate is selected from the group consisting of:
FBGA (Fine Pitch Ball Grid Array), high density (Line and Space) and Ball Pad OSP surface finish PCB/substrate, standard BGA, Chip Scale Packaging (CSP), and system scale PCB's.

16. An integrated circuit (IC) die packaged with a BGA substrate, said BGA substrate configured to be formed into a singulated unit with said IC die; formed by a method comprising the steps of:
a) making electrical connections between said IC die and said BGA substrate, by forming wire bonds with bonding wires between bonding pads on said IC and bond fingers on a first side of said BGA substrate, including forming bond finger wire bonds;
b) testing the electrical integrity of each said bond finger wire bond by
1) sending a voltage pulse through each said bond finger wire bond on said BGA substrate to a grounded feature on said first side of said BGA substrate strip, through an indirect electrical connection pathway at least a portion of which is not present on said singulated unit;
wherein said substrate does not have direct electrical connections on said first side between said bond fingers and said grounded feature; and
2) measuring if there is current flow through said pathway.

17. The integrated circuit (IC) die mounted on and packaged with a BGA substrate as in claim 16, formed by a method further comprising the steps of:
a) forming a package mold on said BGA substrate;
b) attaching solder balls to a second side of said BGA substrate; and
c) singulating said BGA substrate.

18. The integrated circuit die of claim 16, wherein said wire bonds are formed by an automated wire bonding machine, and wherein;
if there is no said current flow through said indirect electrical connection pathway, said automated wire bonding machine is stopped and operator assistance is requested.

19. The method of claim 16, wherein;
said BGA substrate includes a first BGA IC package body region, and a second region outside said BGA IC package body; and
said indirect electrical connection pathway includes a dummy bypass via through said BGA substrate, in said second region outside said BGA IC package body.

20. The integrated circuit die of claim 19, wherein said indirect electrical connection pathway comprises:
a) said wire bond electrically connected to said bond finger;
b) said bond finger electrically connected to a conducting via through said substrate in said first region;
c) said conducting via electrically connected to a solder ball pad on said second side of said substrate;
d) said solder ball pad electrically connected to a bottom side tie bar on said bottom side of said first substrate, through conducting traces;
e) said second side tie bar electrically connected to said conducting dummy bypass via;
f) said dummy bypass via electrically connected to said grounded feature on said top side in said second region;
g) wherein said dummy bypass via is disconnected from said solder ball pad when said BGA substrate is formed into a singulated unit.

21. The method of claim 16, wherein said grounded feature is a mold gate.

22. The method of claim 16, wherein said BGA substrate is selected from the group consisting of:
FBGA (Fine Pitch Ball Grid Array), standard BGA, Chip Scale Packaging (CSP), and system scale PCB's.
